(19) United States
(12) Patent Application Publication
(10) Pub. No.: US 2007/0117261 A1
(43) Pub. Date: May 24, 2007

(54) Multilayer printed wiring board and method for producing the same

(75) Inventors: Yukihiro Ueno, Hiroshima (JP); Yuhji Takamoto, Osaka (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/594,831

(22) Filed: Nov. 9, 2006

(30) Foreign Application Priority Data
Nov. 18, 2005 (JP) 2005-334421

(51) Int. Cl. H01L 21/00; H01L 23/02

(52) U.S. Cl. 438/106; 438/62; 257/678

(57) ABSTRACT

A multilayer printed wiring board includes a flexible portion that is constituted from a flexible base material in which an inner layer circuit pattern has been formed, and a hard portion that is constituted from a hard base material that is layered on a portion of the flexible base material via an adhesive layer and in which an outer layer circuit pattern has been formed. The border of the flexible portion and the hard portion is covered by a covering layer that continuously covers the flexible base material and the hard base material, with an exposed portion of the inner layer circuit pattern being exposed. A plating layer is formed by performing surface treatment (plating) for the exposed portion and the outer layer circuit pattern.

### BACKGROUND OF THE INVENTION

This application claims priority under 35 U.S.C. § 119(a) on Japanese Patent Application No. 2005-334421 filed in Japan on Nov. 18, 2005, the entire contents of which are hereby incorporated by reference.

The present invention relates to a printed wiring board for an electronic device that is used for implementation of an electronic component, and more specifically to a multilayer printed wiring board in which a conductor layer pattern of two or more layers is formed, and that has a flexible portion and a hard portion.

A multilayer printed wiring board that has a flexible portion and a hard portion is commonly referred to as a “flex-rigid wiring board” or a “ multilayer flexible wiring board”, and is often used along with reductions in size, increasing precision, and compounding of an electronic device. This is accompanied by the appearance of various problems, such as problems of unevenness in the vicinity of the border between the flexible portion and the hard portion, problems in surface treatment for an exposed portion of the flexible portion, and the necessity of process simplification.

FIGS. 11 to 15 are explanatory diagrams for explaining the state of a multilayer printed wiring board in each production process for a multilayer printed wiring board according to Conventional Example 1.

FIG. 11 is a cross-sectional diagram that shows a cross-section of a flexible base material that constitutes an inner layer of a multilayer printed wiring board according to Conventional Example 1.

A flexible base material 110 that constitutes an inner layer of a multilayer printed wiring board 101 is provided with an insulation layer 111 and conductor layers 112 and 113 that have been layered on both faces of the insulation layer 111.

In the flexible base material 110, two-sided flexible wiring board material that is ordinarily commercially available is used. The insulation layer 111 is configured with insulating resin film that has flexibility, and ordinarily, is configured with film such as polyimide film, polyether ketone film, or other liquid crystal polymer film.

The conductor layers 112 and 113 are formed layered on both sides of the insulation layer 111 via adhesive, or without adhesive. The conductor layers 112 and 113, ordinarily, are configured with copper foil, but they may also be configured with other metal foil.

The multilayer printed wiring board 101, in a completed state (see FIG. 15), is provided with a hard portion As that has rigidity and a flexible portion Af that is partially formed and has flexibility. Accordingly, in a similar manner, the flexible base material 110 also has a hard corresponding portion As and a flexible corresponding portion Af as regions that correspond to the hard portion As and the flexible portion Af when completed (hereinafter, the hard portion As and the flexible portion Af when completed and the hard corresponding portion As and the. flexible corresponding portion Af during processing are referred to simply as the hard portion As and the flexible portion Af, without distinguishing them from each other). Also, a hard portion Ass is a region that is severed when completed, and is a supplementary hard portion that has a role of holding the flexible portion Af during processing.

FIG. 12 is a cross-sectional diagram that shows a cross-section of a flexible base material in which an inner layer circuit pattern has been formed, in a multilayer printed wiring board according to Conventional Example 1.

By performing patterning for the conductor layers 112 and 113 of the flexible base material 110 shown in FIG. 11, an inner layer circuit pattern 112p (a first conductor layer pattern 112p) and an inner layer circuit pattern 113p (a second conductor layer pattern 113p) are formed.

The inner layer circuit patterns 112p and 113p are formed by applying an etching resist (not shown) to the conductor layers 112 and 113, and after patterning with photolithography technology, etching the conductor layers 112 and 113 using the patterned etching resist as a mask, and separating the etching resist by peeling.

The inner layer circuit patterns 112p and 113p constitute inner layer circuit patterns 112ps and 113p that correspond to the hard portion As, and an inner layer circuit pattern 112pf that corresponds to the flexible portion Af (when it is not necessary to distinguish the inner layer circuit pattern 112ps and the inner layer circuit pattern 112pf, they may simply be referred to as the inner layer circuit pattern 112p). The inner layer circuit pattern 112pf that corresponds to the flexible portion Af, in the completed multilayer printed wiring board 101, is the circuit pattern of the flexible portion, and is configured with the end portion used as an exposed portion 112pt applied as a terminal portion.

The flexible portion Af has a single layer structure, so the inner layer circuit pattern 113p (the second conductor layer pattern 113p) is not formed in the flexible portion Af.

FIG. 13 is a cross-sectional diagram that shows a cross-section of a flexible base material in which a covering layer that covers an inner layer circuit pattern has been formed, in a multilayer printed wiring board according to Conventional Example 1.

In order to protect the inner layer circuit patterns 112p and 113p, and insure insulation from conductor layers 123 and 124 (see FIG. 14) of a hard base material 120, covering layers 130 and 131 that cover the inner layer circuit patterns 112p and 113p are layered on both faces.

The covering layers 130 and 131 are also known as coverlays, and are ordinarily configured with insulating resin film of the same material and approximately the same thickness as the insulation layer 111, and are layered (formed) via adhesive layers 115 and 116 that have been formed affixed to the covering layers 130 and 131 in advance.

The covering layers 130 and 131 are formed in a state in which the exposed portion 112pt, which becomes a terminal portion when complete, has been exposed at the end portion of the inner layer circuit pattern 112pf that corresponds to the flexible portion Af.

Next, gold or tin plating, or surface treatment (not shown) such as rust-proofing processing, is performed on the exposed portion 112pt. For example, in the case of performing gold plating, after performing preprocessing such as polishing or soft etching of the conductor surface, formation of a plating resist on portions where plating is unnecessary, or plating seed formation (seeding), nickel plating is performed in order to improve close fitting, and then gold plating is performed.

FIG. 14 is a cross-sectional diagram that shows a cross-section of a state in which a hard base material that constitutes an outer layer outside of a covering layer has been formed, in a multilayer printed wiring board according to Conventional Example 1. FIG. 15 is a plan view viewed from the direction of arrow A in FIG. 14. In FIG. 15, in order to simplify the drawing, outer layer circuit patterns and the like are omitted, and a simple overview of the borders of hard portions As and Ass, and the flexible portion Af, is shown.

A hard base material 120 that constitutes an outer layer is arranged and layered on both sides of the flexible base material 110 on which surface treatment such as plating has been performed (outside of the covering layers 130 and 131). For the hard base material 120, one-sided wiring board material that is ordinarily commercially available, for example, material that is made harder than the flexible portion Af by layering the conductor layers 123 and 124 of copper foil or the like on insulation layers 121 and 122, which are glass epoxy or polyimide, can be used.

With a layer pressing device or the like, the one-sided wiring board material (the hard base material 120) is layered (bonded) on the covering layers 130 and 131 (the inner layer circuit patterns 112p and 113p of the flexible base material 110) via adhesives 117 and 118. In the region that corresponds to the flexible portion Af, such that the corresponding hard base material 120 can be easily severed and separated in post processing, the adhesives 117 and 118 are configured such that they are not formed.

Arrow B indicates a border B of the flexible portion Af and the hard portion As in the multilayer printed wiring board 101 after completion. In the figures, the side to the right of the border B is the flexible portion Af, and the side to the left is the hard portion As. The hard base material 120 is configured with a slit 120g formed at the border B, so that it is possible to easily remove the hard base material 120 in the region that corresponds to the flexible portion Af.

Afterward, applying an ordinary method for producing a multilayer printed wiring board of through-hole processing, panel plating, outer layer circuit pattern formation (not shown, formed by performing patterning for the conductor layers 123 and 124 of the hard base material 120), solder resist formation, silk printing, and surface treatment such as plating or rust-proofing processing, processing is advanced to just before outer shape processing (FIG. 15).

Inside of the double-chained line in FIG. 15 is the hard portion As and the flexible portion Af of the multilayer printed wiring board 101 as a completed component, and outside of the double-chained line is the hard portion Ass that is severed and removed in the completed multilayer printed wiring board 101.

The slit 120g is formed extended to somewhat outside of the outer shape of the multilayer printed wiring board 101 (120gc). Accordingly, when the position indicated by the double-chained line is punched with a metal die or the like, the hard base material 120, at the slit 120g portion, is separated into two portions, the hard portion As side and the flexible portion Af side.

The hard base material 120 of the hard portion As side is bonded to the covering portions 130 and 131 (the flexible base material 110) via the adhesives 117 and 118 (and adhesives 115 and 116). On the other hand, the hard base material 120 of the flexible portion Af side, because the adhesives 117 and 118 are not present, is merely weakly layered physically with pressure and heat when the hard base material 120 has been layered on the covering portions 130. Accordingly, the hard base material 120 of the region that corresponds to the flexible portion Af can be easily separated.

The hard base material 120 of the flexible portion Af side is not necessary in a completed component, so it is necessary for it to be removed in a process prior to completion of the multilayer printed wiring board 101. That is, in the final process, the hard base material 120 layered corresponding to the flexible portion Af is peeled away with a jig or by hand, and removed from the hard portion Ass, resulting in a completed multilayer printed wiring board 101. A method has also been proposed in which instead of slit processing that forms the slit 120g, a groove is formed in the hard base material 120.

In Conventional Example 1, the covering layer 130 is formed such that it straddles the border of the flexible portion Af and the hard portion As, but after forming the inner layer circuit patterns 112p and 113p, because the covering layer 130 is formed continuously, when layering the hard base material 120 that constitutes an outer layer, it receives much stress at the edge of the hard base material 120, which may cause breaks or fractures when bending.

That is, in order to later remove the hard base material 120 in the region that corresponds to the flexible portion Af, a slit 120g or a groove is formed in advance (or, processing has been performed in advance with the portion that corresponds to the flexible portion Af omitted), so there is the problem that in a state in which the surface of the covering layer 130 has made contact with a corner of the hard base material 120, heat and pressure for layering and bonding are received, and some type of edged tool is pressed against the surface of the covering layer 130, and moreover, the pressures and temperatures applied to either side of the border differ, and considering the materials, injury or damage is received on the surface, and the component is completed in a state in which there is discontinuity of strength, such as in which the degree of hardening or thickness of the adhesive layer 117 changes in the vicinity of the border.

Further, there is the problem that after the covering layer 130 has been layered on the inner layer (the flexible base material 110), layering of the outer layer (the hard base material 120) is performed, so heat and pressure are again applied to the covering layer 130 and the adhesive layers 115 and 116 overharden, affecting the flexibility properties. This overhardening combines with stress when layering at a border B of the flexible portion Af and the hard portion As, and flexibility at the border further worsens.

FIGS. 16 and 17 are explanatory diagrams for describing states of a multilayer printed wiring board according to Conventional Example 2.

FIG. 16 is a cross-sectional diagram that shows a cross-section of a state in which a hard base material has been formed outside of a covering layer, in a multilayer printed wiring board according to Conventional Example 2. FIG. 17 is a plan view viewed from the direction of arrow A in FIG. 16. In FIG. 17, in order to simplify the diagram, outer layer circuit patterns and the like are omitted, and a simple overview of the borders of hard portions As and Ass, and the flexible portion Af, is shown.

The multilayer printed wiring board 101 according to Conventional Example 2 differs from Conventional Example 1 in that slit processing is not performed in advance in the hard base material 120 that is layered on the covering layers 130 and 131. This sort of method can be applied in the case of a brittle substrate that, for example, can be severed/torn away by hand or the like when a particular level of force is applied, such as when the hard base material 120 is, for example, a glass epoxy substrate of not more than 100 μm.

Specifically, with the same procedure as in Conventional Example 1, the hard base material 120 is layered (bonded) outside of the covering layers 130 and 131 in the same manner as the processing up to FIG. 14. However, with Conventional Example 2 as described above, slit processing is not performed in the hard base material 120. Same as in Conventional Example 1, through-hole processing and outer layer circuit pattern formation is performed (by performing patterning for the conductor layers 123 and 124 of the hard base material 120, an outer layer circuit pattern 123p (a third conductor layer pattern 123p) and an outer layer circuit pattern 124p (a fourth conductor layer pattern 124p) are formed, and outer layer circuit patterns 123ps and 124ps constitute the outer layer circuit patterns 123p and 124p, which correspond to the hard portion As).

In Conventional Example 2, unlike in Conventional Example 1, a band-like severing guide pattern 123pd is formed as a portion of the outer layer circuit pattern 123p, so as to sandwich the border B of the hard portion As and the flexible portion Af. That is, the band-like severing guide pattern 123pd is formed with a shape that sandwiches the border B of the hard portion As and the flexible portion Af. Approximately the same operation is obtained by only either one of two severing guide patterns 123pd. Also, it is possible to form the same guide pattern in the outer layer circuit pattern 124p at a position that corresponds to the severing guide pattern 123pd.

In this state, processing steps such as remaining resist formation and silk printing are performed.

Next, as middle hole processing, slit processing is performed at the periphery of the flexible portion Af except for the border portion of the flexible portion Af and the hard portion As, that is, at the border of the flexible portion Af and the hard portion Ass, forming slits 120gf and 120gg (FIG. 17). Ordinarily, when the periphery of the flexible portion Af is completely removed, the flexible portion Af is unstable, so as shown in FIG. 17, the slits 120gf and 120gg are formed discontinuously such that they are connected with small bridges. Due to formation of the slits 120gf and 120gg, the end face of the hard base material 120 is exposed at the slits 120gf and 120gg.

Next, from for example the position of the slit 120gg in which the end portion (end face) of the hard base material 120 is exposed, the hard base material 120 covering the flexible portion Af is severed and peeled away. As described above, the hard base material 120 is formed with a glass epoxy substrate or the like and is thus brittle, so it is comparatively fragile, and can be torn away. Accordingly, the hard base material 120 covering the flexible portion Af, at the border of the flexible portion Af and the hard portion As, can be broken off or torn away. At this time, the severing guide pattern 123pd is a guide when peeling away the hard base material 120, and functions to guard/guide the severing region such that the hard base material 120 is not torn away at an unintended portion.

Afterward, an electrical check is performed, and also final outer shape processing is performed by punching with a metal die or the like at the position indicated by the double-chained line, and by separating from the hard portion Ass, the completed multilayer printed wiring board 101 is formed.

As a method for peeling the hard base material that has been disposed in the region that corresponds to the flexible portion, methods have been proposed in which, for example, a half punch is used in order to peel the hard base material, and methods in which hard base material, which has been removed in advance in the region positioned above the flexible portion, and adhesive are layered such that it is not necessary to perform removal of the hard base material that has been disposed in the region that corresponds to the flexible portion, which is difficult and takes time, and a depression therein is filled with a separate resin or spacer.

With the conventional technology as in, for example, Conventional Examples 1 and 2, it is necessary to perform surface treatment for the inner layer circuit pattern that constitutes the flexible portion and the outer layer circuit pattern that constitutes the hard portion respectively, so it is necessary to perform surface treatment at least twice, for example metal plating or the like.

That is, there are the problems that (1) manufacturability is diminished because processing is difficult and long, and (2) after surface treatment of the flexible portion there is heat processing and wet processing such as layer pressing of the hard portion or outer layer circuit pattern formation, and further, the flexible portion is placed in a sealed environment by the hard base material, and thus a phenomenon occurs in which the flexible portion on which predetermined surface treatment has been performed is contaminated by gas or adhesive flow generated during processing, various impregnated processing agents, water, or the like.

In order to address these problems, it necessary to move the surface treatment of the flexible portion (the inner layer circuit pattern) as much later as possible. Specifically, it is preferable to perform that surface treatment immediately prior to outer shape processing near completion, or alternatively, to perform that surface treatment together with the plating or surface treatment processing of the outer layer circuit pattern, considering reduction of the number of processes. However, because a large difference in the thickness of the flexible portion and the hard portion is produced, unified processing of the flexible portion (inner layer circuit pattern) and the outer layer circuit pattern, as stated next, is difficult and could not be realized in the conventional technology.

That is, when performing gold plating or tin plating, or surface treatment such as rust-proofing processing, various preprocessing such as purification of the conductor layer surface to be processed is necessary. This preprocessing includes physical processing such as-brush polishing.

However, although the flexible portion is configured with the flexible base material (for example, insulating resin film alone) and has a comparatively thin structure, the hard portion is configured from the covering layer and adhesive, interlayer insulating resin, and the like, and is configured relatively quite thick in order to have rigidity. For example, in the case of a standard multilayer printed wiring board having four conductor layers (circuit patterns), the thickness of the flexible portion including the covering layer is about 50 μm, while on the other hand the thickness of the hard portion is about 0.6 m, which is approximately ten times the thickness of the flexible portion.

Accordingly, in the vicinity of the border of the hard portion and the flexible portion, because there is a large height difference, the polishing brush does not make good contact, conversely, there is the problem that processing with the polishing brush damages the corners of the hard portion. Also, when performing plating processing, formation of a plating resist or the like is necessary, but in the vicinity of the border of the flexible portion and the hard portion a portion is produced in which the resist does not fit closely, so there is the problem that processing such as plating processing cannot be performed normally.

Also, when providing a thermocompression pressing process in order to layer and bond the covering layer (coverlay) in the next processing after processing of the flexible base material, the dimensions of the flexible base material change, and this is disadvantageous when manufacturing a high-precision, high-density multilayer printed wiring board. On the other hand, methods have been proposed in which an ink covering layer is executed in the flexible portion in order to lower heat and pressure stress, but there is the problem that the flexibility properties of the flexible portion are poor compared to the covering layer of the insulating resin film.

Further, in the hard portion and the flexible portion, because there is a large difference in materials and structure (for example, such as a height difference), there is the problem that discontinuity in strength/structure causes damage to the conductor of the flexible portion or the hard base material when layering and pressing the covering layer or the hard base material, impairing flexibility in the base of the flexible portion. Such a problem thus requires separate measures such as resin sealing or the like in the vicinity of the border.

With a conventional flex-rigid wiring board, the portion that maintains insulation between an inner layer conductor layer, such as thin prepreg, or alternatively, RCC (resin-coated copper) or the like, and an outer layer conductor layer, cannot insure thickness to the extent of the hard multilayer printed wiring board, and insulation performance is somewhat inadequate, so in actuality, this problem is dealt with by supplementing insulation performance with the covering layer, which is insulating resin film.

However, in order to address the problems in the conventional technology described above, it has been thought first necessary to abolish layering of a covering layer on a flexible base material that constitutes an inner layer in a hard portion, and reduce the total thickness of the multilayer printed wiring board (hard portion). That is, this is a method in which, in principle, an attempt is made to configure a covering layer only in the flexible portion.

Further, recently, the insulation performance of resin has improved, and it has become possible to satisfy insulation properties without necessarily providing a covering layer. Accordingly, it has become possible to reduce the total thickness of the multilayer printed wiring board (the hard portion) by configuring the covering layer in only the flexible portion.

However, although the total thickness of the hard portion has certainly been reduced, when viewing a cross-section of the hard portion in the vicinity of the border of the hard portion and the flexible portion, the covering portion expected to be formed in only the flexible portion enters into the hard portion, and thus the structural discontinuity in the vicinity of the border is not at all changed from the conventional technology.

The reason is that in order to maintain the flexibility properties of the flexible portion, and remove the possibility of the inner layer circuit pattern in the flexible portion breaking at the border with the hard portion, or alternatively, to avoid a portion of the inner layer circuit pattern of the flexible portion not being covered by the covering layer and thus being exposed, due to displacement when layering the hard portion or forming the covering layer, it is essential to provide an overlap at the position of the hard portion and the covering layer, and so it is not possible to avoid overlap. Also, due to such an overlap phenomenon the vicinity of the border becomes mountain-like (with a step-like height difference), and in return surface treatment becomes difficult.

That is, with the measures taken in the conventional technology, there is not any improvement made with respect to the problem of attempting to solve, that is, being able to perform surface treatment as preprocessing for the inner layer circuit pattern and the outer layer circuit pattern at the same time, and being able to reliably perform surface treatment in the vicinity of the border of the flexible portion and the hard portion. Also, even if the total thickness of the multilayer printed wiring board (the hard portion) as a whole is reduced, the problem remains that unified surface treatment for the inner layer circuit pattern and the outer layer circuit pattern is not possible. Also, because layering and pressing of the covering layer is performed after the inner layer circuit pattern has been formed, the problems of maintaining dimensional precision of the inner layer circuit pattern or positioning precision in the inner layer circuit pattern and the outer layer circuit pattern are not solved.

As patent documents that disclose the various conventional technology described above with respect to a multilayer printed wiring board provided with a hard portion and a flexible portion, JP H07-135393A, JP H07-183663A, JP H04-34993A, JP H05-90756A, JP H03-24374A, JP H03-290990A, JP H07-50456A, JP H05-95190A, JP H03-222496A, JP H07-106728A, JP H04-212494A, JP H05-48268A, and JP H06-37408A are known.

The present invention was made in view of the circumstances of the conventional technology described above, and it is an object thereof to provide a multilayer printed wiring board in which the problems in the conventional technology are addressed by effectively using a wiring base material (fiber-reinforced thin prepreg or wiring base material known as RCC applicable to flexible base material, hard base material, a covering layer, or the like) in which thinning and improvement of insulation properties is advanced, and a method for producing that multilayer printed wiring board.

### SUMMARY OF THE INVENTION

It is an object of the present invention to provide a multilayer printed circuit board having high flexibility properties, in which after an inner layer and an outer layer have been formed layered, by forming in common a covering layer that continuously covers a flexible base material and a hard base material in a state in which an exposed portion of an inner layer circuit pattern has been exposed, structural and strength-wise discontinuity from a flexible portion to a hard portion is eliminated.

That is, in order to address the above problems, the multilayer printed wiring board according to the present invention comprises: a flexible portion that is constituted from a flexible base material in which an inner layer circuit pattern has been formed, and a hard portion that is constituted from a hard base material that is layered on a portion of the flexible base material and in which an outer layer circuit pattern has been formed, and a covering layer that continuously covers the flexible base material and the hard base material, with an exposed portion of the inner layer circuit pattern being exposed.

With this configuration, it is possible to reduce the height difference at the border of the flexible portion and the hard portion, and the covering layer (coverlay) can be shared as a single body by the flexible portion and the hard portion, so sufficient filling of the covering layer for the height difference is possible, and it is possible to improve strength-wise discontinuity in the covering layer from the flexible portion to the hard portion, so stable, high flexibility properties (flexibility) can be obtained. Also, conventionally necessary additional structures such as resin processing for the sake of strength at the border of the flexible portion and the hard portion are not needed, so it is possible to provide a multilayer printed wiring board that has high reliability and excellent flexibility.

In the multilayer printed wiring board according to the present invention, in the above configuration, the covering layer may be insulating resin film.

With this configuration, it is possible to easily form the covering layer as a continuous single body from the flexible portion to the hard portion, so the structure is simplified, and reliability can be improved.

In the multilayer printed wiring board according to the present invention, in the above configuration, the covering layer may be formed with the same raw material as an insulation layer of the flexible base material.

With this configuration, a covering layer can be achieved that is easily applied, and that can adequately fill the height difference at the border of the flexible portion and the hard portion, and that has manufacturability and high reliability.

In the multilayer printed wiring board according to the present invention, in the above configuration, the covering layer may be formed with any one selected from the group consisting of polyimide, polyether ketone, polyester, and liquid crystal polymer.

With this configuration, a covering layer can be achieved that is easily applied, and that has manufacturability and high reliability.

In the multilayer printed wiring board according to the present invention, in the above configuration, the covering layer may include a first covering layer that continuously covers a partial region of the hard base material and the flexible base material, and a second covering layer that covers a region other than the partial region of the hard base material.

With this configuration, it is possible for the covering layer to have a form as necessary, and to have manufacturability and good properties.

In the multilayer printed wiring board according to the present invention, in the above configuration, the first covering layer may be insulating resin film, and the second covering layer may be formed with the same material or a different material than the first covering layer.

With this configuration, it is possible for the covering layer to have a form as necessary, and to have manufacturability and good properties.

In the multilayer printed wiring board according to the present invention, in the above configuration, the second covering layer may be formed with insulating resin film or insulating resin ink.

With this configuration, it is possible for the covering layer to have a form as necessary, and to have manufacturability and good properties.

Also, it is another object of the present invention to provide a method for producing a multilayer printed wiring board in which by layering a hard base material that constitutes a hard portion on a flexible base material in which an inner layer circuit pattern is formed, and forming a covering layer that continuously covers the flexible base material and the hard base material in a state in which an exposed portion of the inner layer circuit pattern has been exposed, and next performing surface treatment for the exposed portion, dimensional precision of the inner layer circuit pattern, and precision of positioning of the inner layer circuit pattern and the outer layer circuit pattern relative to each other, are improved, and by making it unnecessary to perform layer pressing of the covering layer in the processing from after inner layer formation to before outer layer formation, work efficiency is improved, and moreover, by making it possible to perform unified surface treatment for the inner layer circuit pattern and the outer layer circuit pattern, surface treatment is simplified, and by insuring cleanliness of the region where surface treatment is performed, a high quality product can be provided.

That is, in order to address the problems described above, the method for producing a multilayer printed wiring board according to the present invention includes, in a method for producing a multilayer printed wiring board including a flexible portion that is constituted from a flexible base material in which an inner layer circuit pattern has been formed, and a hard portion that is constituted from a hard base material that is layered on a portion of the flexible base material and in which an outer layer circuit pattern has been formed, a step of patterning a conductor layer of the flexible base material to form the inner layer circuit pattern, and a step of bonding the hard base material in a region that corresponds to the hard portion of the flexible base material in which the inner layer circuit pattern was formed, and a step of forming a covering layer that continuously covers the flexible base material and the hard base material, with an exposed portion of the inner layer circuit pattern being exposed, and a step of performing surface treatment for the exposed portion of the inner layer circuit pattern after the covering layer is formed.

With this configuration, processing that forms a covering layer before layering the hard base material on the flexible base material (coverlay formation processing that accompanies heat layering) is unnecessary, so it is possible to improve dimensional precision and wiring density of the inner layer circuit pattern, and a high-performance multilayer printed wiring board can be produced in which the positioning precision of the inner layer circuit pattern and the outer layer circuit pattern is high. Also, processing that performs surface treatment for the inner layer circuit pattern before layering the hard base material on the flexible base material is unnecessary, so there is no effect at all on dimensional precision of the inner layer circuit pattern due to surface treatment or preprocessing for the inner layer circuit pattern, and thus it is possible to realize a multilayer printed wiring board for which high dimensional precision is insured. Also, it is possible to insure cleanliness in a region where surface treatment of the exposed portion of the inner layer circuit pattern or the like is performed, so it is possible to easily produce a multilayer printed wiring board with high quality and high reliability. Further, processing that removes the hard base material that corresponds to the flexible portion is unnecessary, so it is possible to simplify processing and improve work efficiency.

In the method for producing a multilayer printed wiring board according to the present invention, in the above method, a step of patterning a conductor layer of the hard base material to form the outer layer circuit pattern before forming the covering layer is included, and in the step of performing surface treatment, surface treatment for the outer layer circuit pattern may be performed at the same time.

With this configuration, it is not necessary to individually perform surface treatment for the exposed portion of the inner layer circuit pattern and surface treatment for the outer layer circuit pattern, so it is possible to dramatically simplify surface treatment processing, and man-hours can be reduced.

In the method for producing a multilayer printed wiring board according to the present invention, in the above method, an outer layer circuit pattern etching resist used when forming the outer layer circuit pattern may be formed as a single body in the hard portion and the flexible portion.

With this configuration, it is possible to avoid effects on the inner layer circuit pattern in the outer layer circuit pattern formation process, simplifying processing.

In the method for producing a multilayer printed wiring board according to the present invention, in the above method, an additional layer may be formed in the outer layer circuit pattern etching resist formed in the flexible portion.

With this configuration, because the flexible portion has a two-layer structure, the height difference of the flexible portion and the hard portion is diminished, and it is possible to reliably perform filling at the border of the flexible portion and the hard portion, so it is possible to avoid the occurrence of defects at the border.

In the method for producing a multilayer printed wiring board according to the present invention, in the above method, either one of the outer layer circuit pattern etching resist and the additional layer may be formed with a printing method.

With this configuration, it is possible to easily form a two-layer structure.

Also, it is another object of the present invention to provide a method for producing a multilayer printed wiring board in which by layering a hard base material that constitutes a hard portion on a flexible base material in which an inner layer circuit pattern is formed, removing the hard base material of the region that corresponds to the flexible portion after the outer layer circuit pattern is formed in the hard base material, and forming a covering layer that continuously covers the flexible base material and the hard base material in a state in which an exposed portion of the inner layer circuit pattern has been exposed, dimensional precision of the inner layer circuit pattern, and precision of positioning of the inner layer circuit pattern and the outer layer circuit pattern relative to each other, can be improved, and because unified surface treatment for the inner layer circuit pattern and the outer layer circuit pattern is possible, surface treatment processing is simplified so that cleanliness of the region where surface treatment is performed can be insured, and thus a high quality product can be provided.

That is, in order to address the above problems, the method for producing a multilayer printed wiring board according to the present invention includes, in a method for producing a multilayer printed wiring board including a flexible portion that is constituted from a flexible base material in which an inner layer circuit pattern has been formed, and a hard portion that is constituted from a hard base material that is layered on a portion of the flexible base material and in which an outer layer circuit pattern has been formed, a step of patterning a conductor layer of the flexible base material to form the inner layer circuit pattern, and a step of bonding the hard base material in a region that corresponds to the hard portion of the flexible base material, such that the hard base material is faced toward the flexible base material in which the inner layer circuit pattern was formed, and a step of patterning a conductor layer of the hard base material to form the outer layer circuit pattern, and a step of removing the hard base material of a region that corresponds to the flexible portion, and a step of forming a covering layer that continuously covers the flexible base material and the hard base material, with an exposed portion of the inner layer circuit pattern being exposed.

With this configuration, processing that forms a covering layer before layering the hard base material on the flexible base material (coverlay formation processing that accompanies heat layering) is unnecessary, so it is possible to improve dimensional precision and wiring density of the inner layer circuit pattern, and a high-performance multilayer printed wiring board can be produced in which the positioning precision of the inner layer circuit pattern and the outer layer circuit pattern is high. Also, processing that performs surface treatment for the inner layer circuit pattern before layering the hard base material on the flexible base material is unnecessary, so there is no effect at all on dimensional precision of the inner layer circuit pattern due to surface treatment or preprocessing for the inner layer circuit pattern, and thus it is possible to realize a multilayer printed wiring board for which high dimensional precision is insured. Also, it is possible to insure cleanliness in a region where surface treatment of the exposed portion of the inner layer circuit pattern or the like is performed, so it is possible to easily produce a multilayer printed wiring board with high quality and high reliability.

In the method for producing a multilayer printed wiring board according to the present invention, in the above method, bonding of the hard base material may be performed on both sides of the flexible base material, with the hard base material arranged on both sides of the flexible base material

With this configuration, it is possible for the outer layer circuit pattern to have multiple layers.

In the method for producing a multilayer printed wiring board according to the present invention, in the above method, a step of performing surface treatment for at least one of the exposed portion and the outer layer circuit pattern, after the covering layer is formed, may also be included.

With this configuration, it is possible to perform surface treatment on a necessary region in a state in which cleanliness is maintained.

In the method for producing a multilayer printed wiring board according to the present invention, in the above method, the covering layer may include a first covering layer that continuously covers a partial region of the hard base material and the flexible base material, and a second covering layer that covers a region other than the partial region of the hard base material.

With this configuration, along with reliably filling at the border of the hard portion and the flexible portion, it is possible to form the covering layer with a form as necessary.

In the method for producing a multilayer printed wiring board according to the present invention, in the above method, the first covering layer and the second covering layer may be insulating resin films that have been formed as a single body.

With this configuration, it is possible to easily form the covering layer with insulating resin film.

In the method for producing a multilayer printed wiring board according to the present invention, in the above method, the first covering layer and the second covering layer may be photosensitive resists that have been formed as a single body.

With this configuration, it is possible to easily form the covering layer with a photosensitive resist.

In the method for producing a multilayer printed wiring board according to the present invention, in the above method, a configuration may be adopted in which either the first covering layer is insulating resin film and the second covering layer is a photosensitive resist, or the first covering layer is a photosensitive resist and the second covering layer is insulating resin film.

With this configuration, it is possible to apply a covering layer with material properties as necessary.

As described above, according to the present invention, an effect is exhibited in which because a covering layer is formed after forming an inner layer and an outer layer, and the covering layer is shared by a flexible portion and at least part of a hard portion, the covering layer can be configured as a single body from the flexible portion to the hard portion over the border of the flexible portion and the hard portion. Thus, additional, resin processing for the sake of reinforcement at the border of the a flexible portion Af (see embodiments below) and a hard portion As (see embodiments below) used in the conventional technology is made unnecessary, and along with this, a multilayer printed wiring board is possible in which flexibility is provided, and in which structural and strength-wise discontinuity is greatly improved over the conventional methods.

Also, according to the present invention, an effect is exhibited in which layer pressing of the covering layer, which is a heat layering process, is not performed in the processing after inner layer formation and before outer layer formation, so work efficiency can be improved, and it is possible to easily manufacture a multilayer printed wiring board in which dimensional precision and wiring density are high, and in which there is high precision of positioning of the inner layer circuit pattern and the outer layer circuit pattern relative to each other.

Also, according to the present invention, an effect is exhibited in which surface treatment for the exposed portion (terminal portion) of the inner layer circuit pattern is performed after outer layer (outer layer circuit pattern) formation, so (1) surface treatment for the exposed portion and the outer layer circuit pattern can be performed together at the same time,. so it is possible to dramatically simplify surface treatment processing, and reduce man-hours, (2) it is possible to maintain cleanliness of portions such as the exposed portion where surface treatment is performed, so a high quality product can easily be produced, and (3) the configuration is such that the inner layer (flexible base material) is not affected (changes in size or the like) by surface treatment or preprocessing thereof before the outer layer (hard base material) is layered, so it is possible to maintain high dimensional precision.

### BRIEF DESCRIPTION OF THE DRAWINGS

FIG. 1 is a cross-sectional diagram that shows a cross-section of a flexible base material that constitutes an inner layer and a flexible portion, in a multilayer printed wiring board according to Embodiment 1 of the present invention.

FIG. 2 is a cross-sectional diagram that shows a cross-section of a flexible base material in which an etching resist for forming an inner layer circuit pattern has been formed, in a multilayer printed wiring board according to Embodiment 1 of the present invention.

FIG. 3 is a cross-sectional diagram that shows a cross-section of a flexible base material in which an inner layer circuit pattern has been formed, in a multilayer printed wiring board according to Embodiment 1 of the present invention.

FIG. 4 is a cross-sectional diagram that shows a cross-section of a state in which a hard base material that constitutes an outer layer and an outer layer circuit pattern have been formed outside of an inner layer, in a multilayer printed wiring board according to Embodiment 1 of the present invention.

FIG. 5 is a cross-sectional diagram that shows a cross-section of a state in which a hard base material of a region that corresponds to a flexible portion has been removed, in a multilayer printed wiring board according to Embodiment 1 of the present invention.

FIG. 6 is a cross-sectional diagram that shows a cross-section of a state in which a covering layer has been formed across the border of a flexible portion and a hard portion, in a multilayer printed wiring board according to Embodiment 1 of the present invention.

FIG. 7 is a cross-sectional diagram that shows a cross-section of a state in which surface treatment has been performed after forming a covering layer, in a multilayer printed wiring board according to Embodiment 1 of the present invention.

FIG. 8 is a cross-sectional diagram that shows a cross-section of a state in which a covering layer has been formed, in a multilayer printed wiring board according to Embodiment 2 of the present invention.

FIG. 9 is a cross-sectional diagram that shows a cross-section of a state in which a hard base material that constitutes an outer layer has been formed outside of an inner layer, in a multilayer printed wiring board according to Embodiment 3 of the present invention.

FIG. 10 is a cross-sectional diagram that shows a cross-section of a state in which a photosensitive resist for forming an outer layer circuit pattern in a hard base material has been formed, in a multilayer printed wiring board according to Embodiment 3 of the present invention.

FIG. 11 is a cross-sectional diagram that shows a cross-section of a flexible base material that constitutes an inner layer, in a multilayer printed wiring board according to Conventional Example 1.

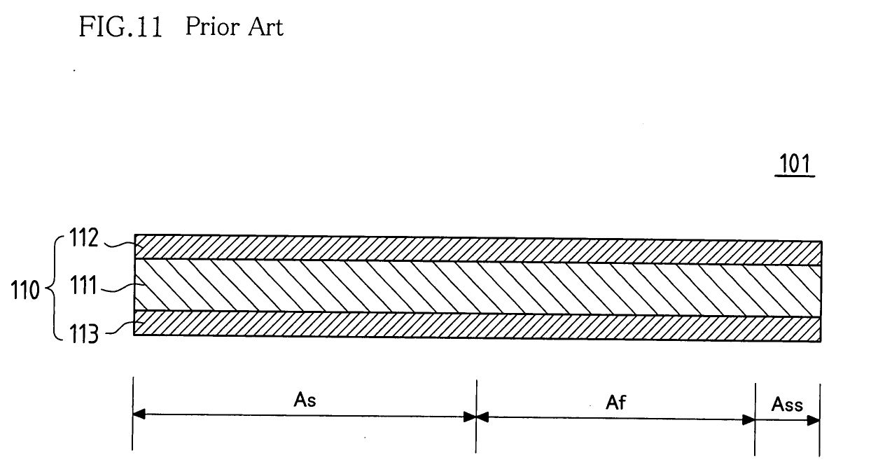

FIG. 12 is a cross-sectional diagram that shows a cross-section of a flexible base material in which an inner layer circuit pattern has been formed, in a multilayer printed wiring board according to Conventional Example 1.

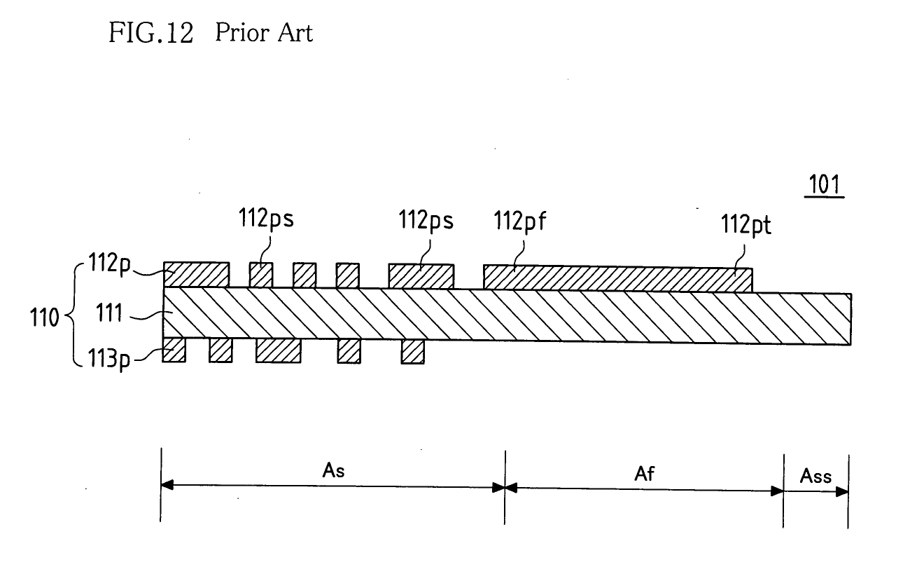

FIG. 13 is a cross-sectional diagram that shows a cross-section of a flexible base material in which a covering layer that covers an inner layer circuit pattern has been formed, in a multilayer printed wiring board according to Conventional Example 1.

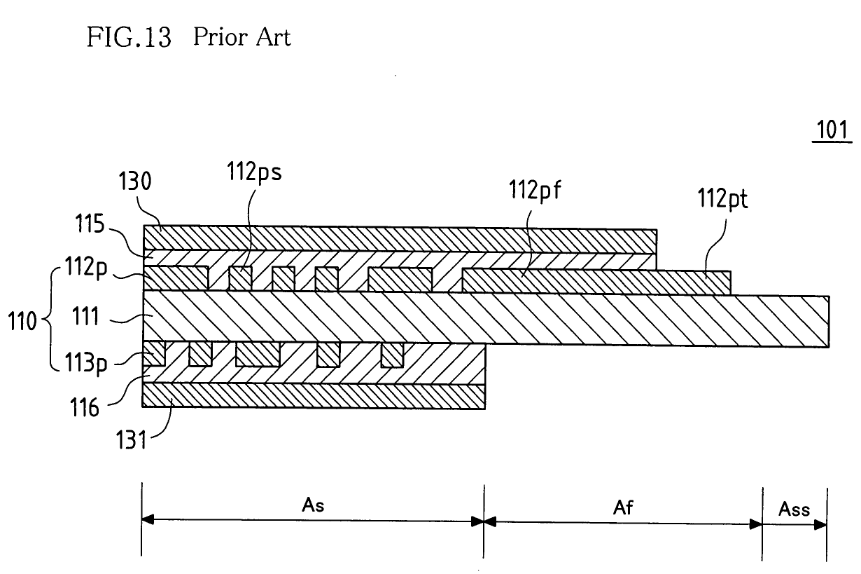

FIG. 14 is a cross-sectional diagram that shows a cross-section of a state in which a hard base material that constitutes an outer layer has been formed outside of a covering layer, in a multilayer printed wiring board according to Conventional Example 1.

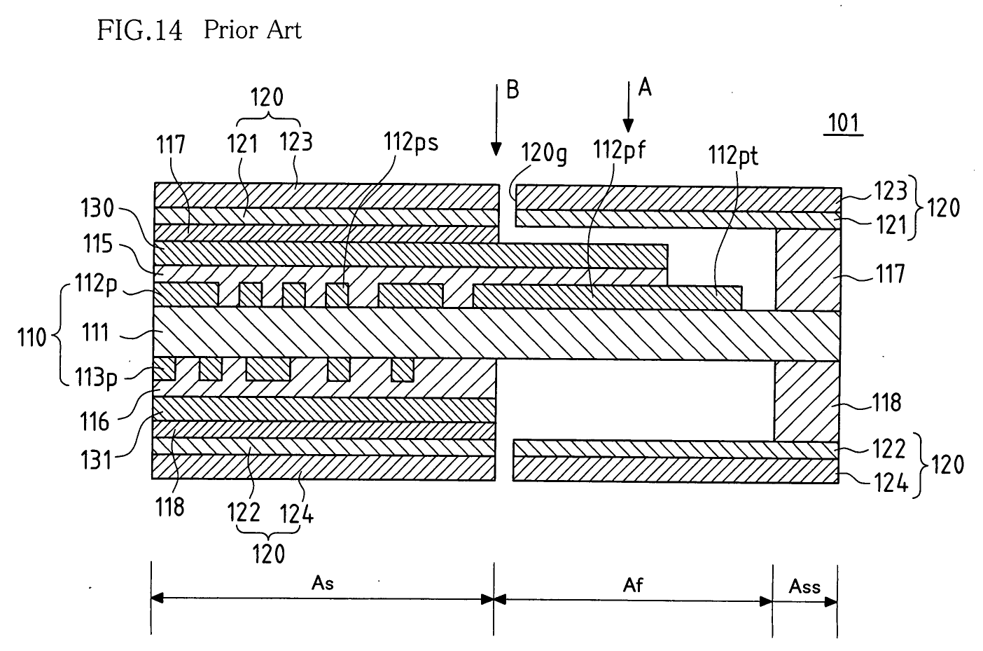

FIG. 15 is a plan view viewed from the direction of arrow A in FIG. 14.

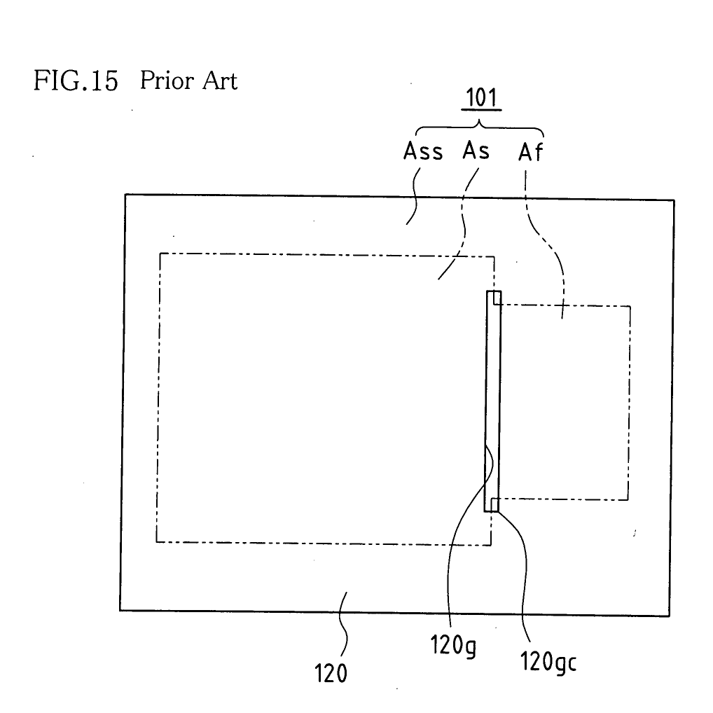

FIG. 16 is a cross-sectional diagram that shows a cross-section of a state in which a hard base material has been formed outside of a covering layer, in a multilayer printed wiring board according to Conventional Example 2.

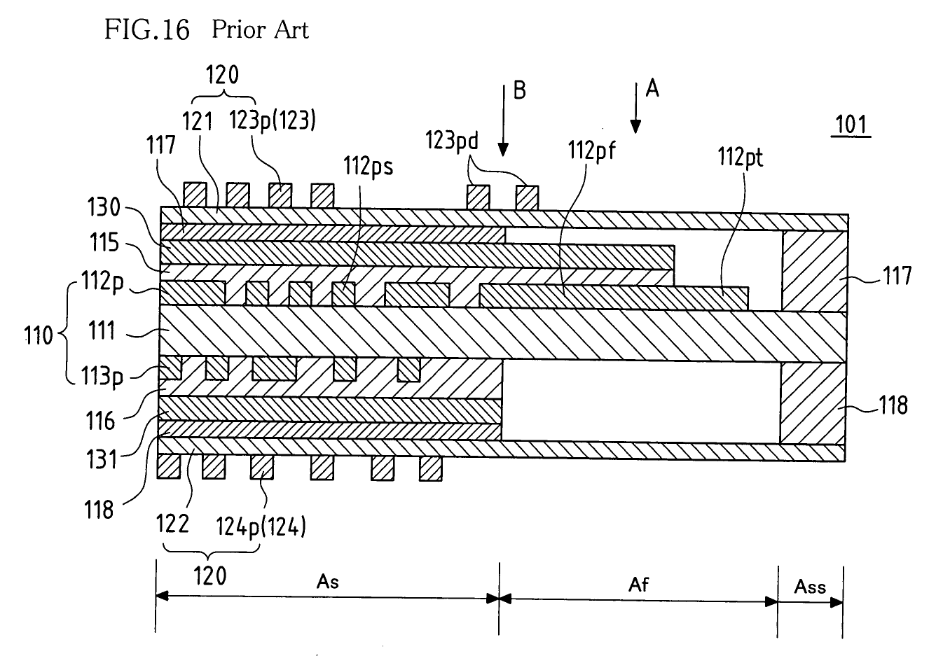

FIG. 17 is a plan view viewed from the direction of arrow A in FIG. 16.

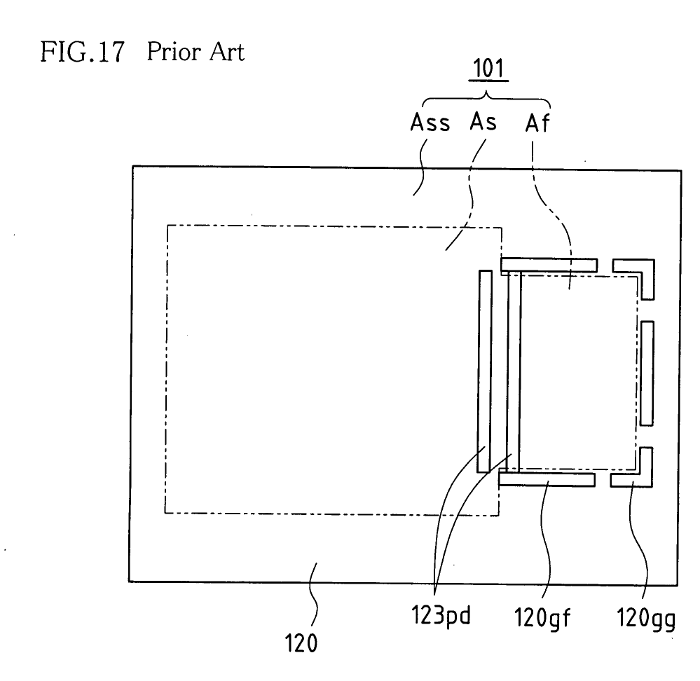

### DESCRIPTION OF THE PREFERRED EMBODIMENTS

Hereinafter, embodiments of the present invention will be described with reference to the accompanying drawings.

### Embodiment 1

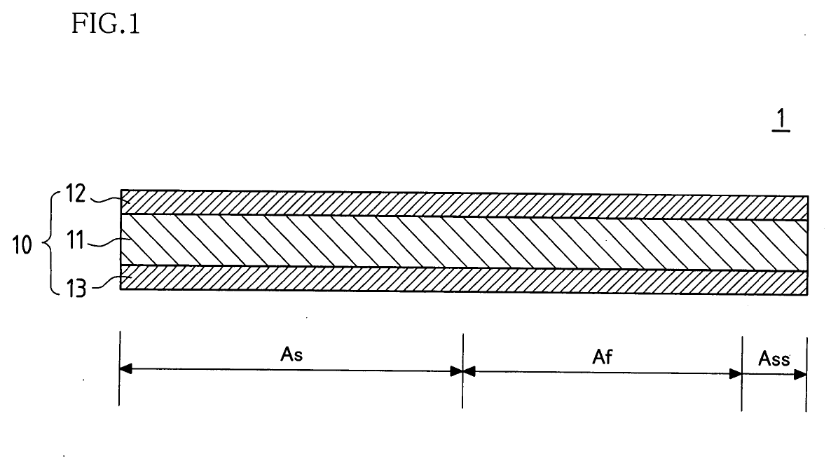

FIGS. 1 to 7 are explanatory diagrams for explaining the state of a multilayer printed wiring board in each production process for a multilayer printed wiring board according to Embodiment 1 of the present invention.

FIG. 1 is a cross-sectional diagram that shows a cross-section of a flexible base material that constitutes an inner layer and a flexible portion, in a multilayer printed wiring board according to Embodiment 1 of the present invention.

A flexible base material 10 that constitutes an inner layer and a flexible portion Af of a multilayer printed wiring board 1 is provided with an insulation layer 11 and conductor layers 12 and 13 that have been layered on both faces of the insulation layer 11. Below, this is referred to as the multilayer printed wiring board 1 even in the midst of processing.

As the flexible base material 10, two-sided flexible wiring board material that is ordinarily commercially available can be used. The insulation layer 11 is configured with insulating resin film that has flexibility, and ordinarily, is configured with insulating resin film such as polyimide film, polyether ketone film, or other liquid crystal polymer film.

The conductor layers 12 and 13 are formed layered on both sides of the insulation layer 11 via adhesive, or without adhesive. The conductor layers 12 and 13, ordinarily, are configured with copper foil, but they may also be configured with other metal foil.

In the present embodiment, in the flexible base material 10, two-sided flexible wiring board material is used in which 12.5 to 25 μm of copper foil is layered and bonded on both faces of polyimide film with a thickness of 25 μm.

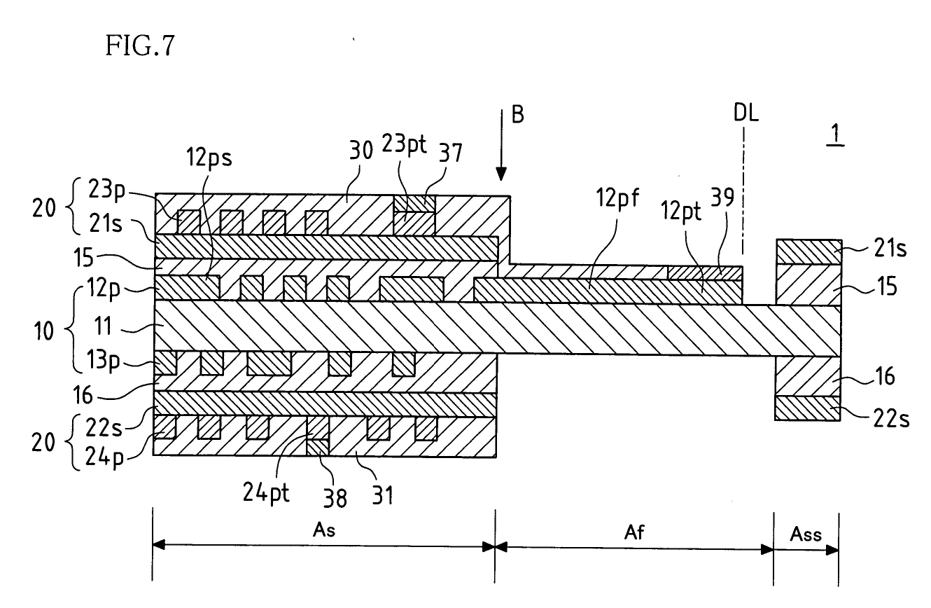

The multilayer printed wiring board 1, in a completed state (see FIG. 7), is provided with a hard portion As that has rigidity and a flexible portion Af that is partially formed and has flexibility. Accordingly, in a similar manner, the flexible base material 10 also has a hard corresponding portion As and a flexible corresponding portion Af as regions that correspond to the hard portion As and the flexible portion Af when completed (hereinafter, the hard portion As and the flexible portion Af when completed and the hard corresponding portion As and the flexible corresponding portion Af during processing are referred to simply as the hard portion As and the flexible portion Af, without distinguishing them from each other). Also, a hard portion Ass is a region that is severed when completed, and is a supplementary hard portion that has a role of holding the flexible portion Af during processing.

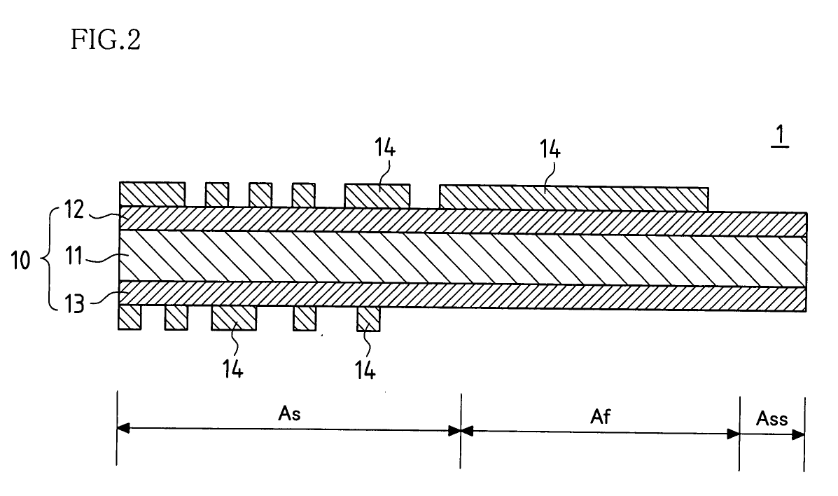

FIG. 2 is a cross-sectional diagram that shows a cross-section of a flexible base material in which an etching resist for forming an inner layer circuit pattern has been formed, in a multilayer printed wiring board according to Embodiment 1 of the present invention.

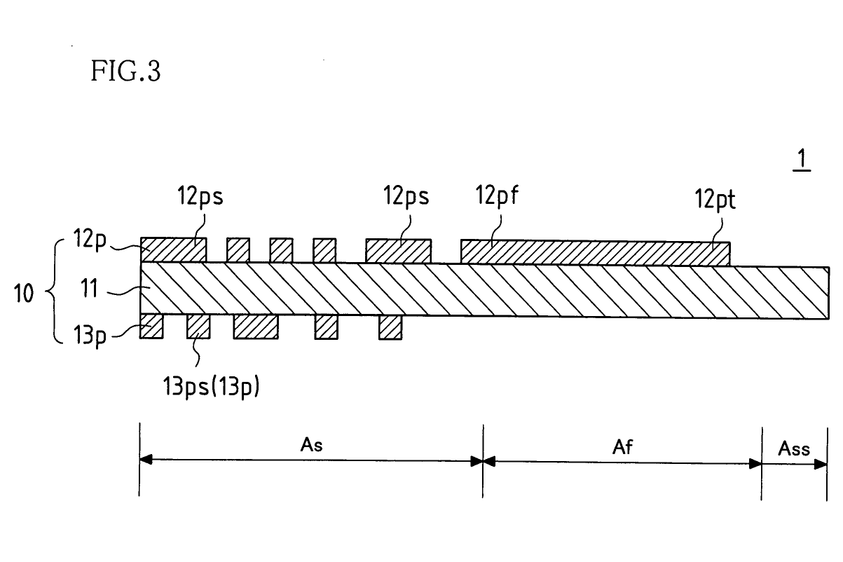

By performing patterning for the conductor layers 12 and 13 of the flexible base material 10 shown in FIG. 1, an inner layer circuit pattern 12p (a first conductor layer pattern 12p) and an inner layer circuit pattern 13p (a second conductor layer pattern 13p) are formed (see FIG. 3).

That is, an etching resist 14 is applied to the conductor layers 12 and 13, and patterning corresponding to inner layer circuit patterns 12p and 13p to be formed is performed with photolithography technology, which is commonly known technology.

FIG. 3 is a cross-sectional diagram that shows a cross-section of a flexible base material in which an inner layer circuit pattern has been formed, in a multilayer printed wiring board according to Embodiment 1 of the present invention.

Using the etching resist 14 patterned in FIG. 2 as a mask, the conductor layers 12 and 13 are etched with a suitable etchant (etching solution) such as a cupric chloride solution, and the etching resist is separated by peeling, thus forming the inner layer circuit patterns 12p and 13p.

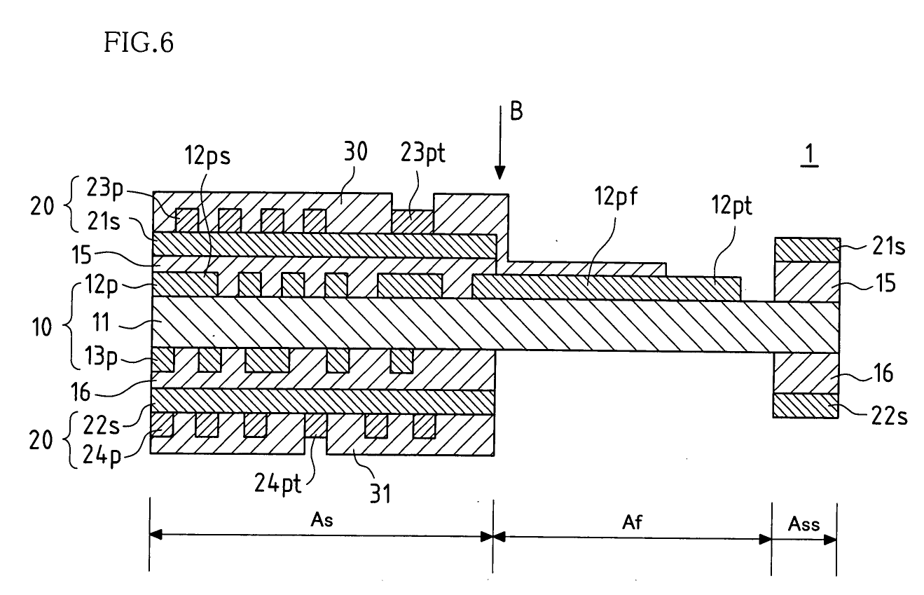

The inner layer circuit patterns 12p and 13p are configured from inner layer circuit patterns 12ps and 13ps that correspond to the hard portion As, and an inner layer circuit pattern 12pf that corresponds to the flexible portion Af (when it is not necessary to distinguish the inner layer circuit pattern 12ps and the inner layer circuit pattern 12pf, they may simply be referred to as the inner layer circuit pattern 12p). The inner layer circuit pattern 12pf that corresponds to the flexible portion Af, in the completed multilayer printed wiring board 1, is the circuit pattern of the flexible portion, and is configured with the end portion used as an exposed portion 12pt applied as a terminal portion (see FIG. 6). That is, the exposed portion 12pt that becomes a terminal portion is formed in the end of the inner layer circuit pattern 12pf, and constitutes a portion that is the subject of surface treatment such as metal plating in post-processing.

In the present embodiment, the flexible portion Af has a single layer structure, so the inner layer circuit pattern 13p (the second conductor layer pattern 13p) is not formed in the flexible portion Af. Below, the inner layer circuit pattern 13ps is referred to simply as the inner layer circuit pattern 13p.

When an inner layer inner via hole is necessary, through-hole processing, or if necessary, hole-filling processing, are performed in advance. This is the same as the conventional technology.

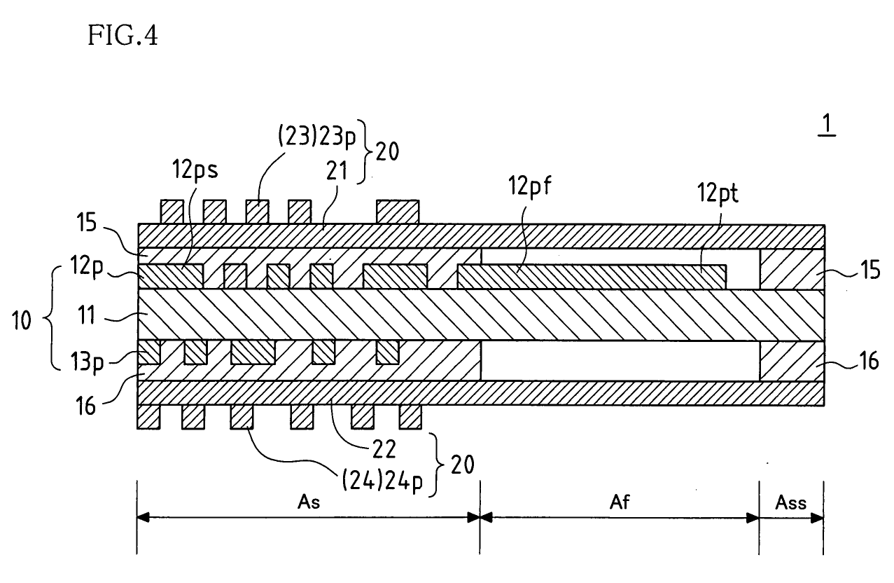

FIG. 4 is a cross-sectional diagram that shows a cross-section of a state in which a hard base material that constitutes an outer layer and an outer layer circuit pattern have been formed outside of an inner layer, in a multilayer printed wiring board according to Embodiment 1 of the present invention.

After forming the inner layer circuit patterns 12p and 13p (FIG. 3), via adhesive layers 15 and 16 in which a portion that makes contact with the flexible portion Af is window punch-processed with a metal die in advance, a hard base material 20 is layered on both faces of the multilayer printed wiring board 1. It is also possible to apply a prepreg instead of the adhesive layers 15 and 16. Also, as the hard base material 20, it is possible to apply one-sided wiring board material in which an insulation layer 21 and a conductor layer 23, and an insulation layer 22 and a conductor layer 24, are respectively layered. For example it is possible to apply one-sided FPC material, one-sided hard substrate material, or the like. The thickness of the adhesive layers 15 and 16, and the thickness of the hard base material 20, is thinly adjusted in advance so as to be an appropriate thickness.

For example, a 25 μm semi-hardened modified acrylic resin sheet was used as the adhesive layers 15 and 16, and polyimide base one-sided FPC material with a thickness of 12.5 μm or 25 μm was used as the hard base material 20.

When further increasing the rigidity of the hard portion As, a material in which a thin glass cloth-containing epoxy is provided in the base may also be used, but in this case as well, a smaller thickness is preferable, and a target of not more than 80 μm was set by the inventor in the embodiments. Covering layer layering processing as in the conventional examples described above is not performed in the processes up until the hard base material 20 is layered corresponding to the flexible base material 10, which is one characteristic of the present embodiment.

By pattering the conductor layers 23 and 24 of the hard base material 20 with a commonly known method after layering of the hard base material 20 is finished, an outer layer circuit pattern 23p (a third conductor layer pattern 23p) and an outer layer circuit pattern 24p (a fourth conductor layer pattern 24p) are formed. At this time, it is also possible to simultaneously form a through-hole. In FIG. 4, for the sake of simplification, a through-holes and via holes are omitted.

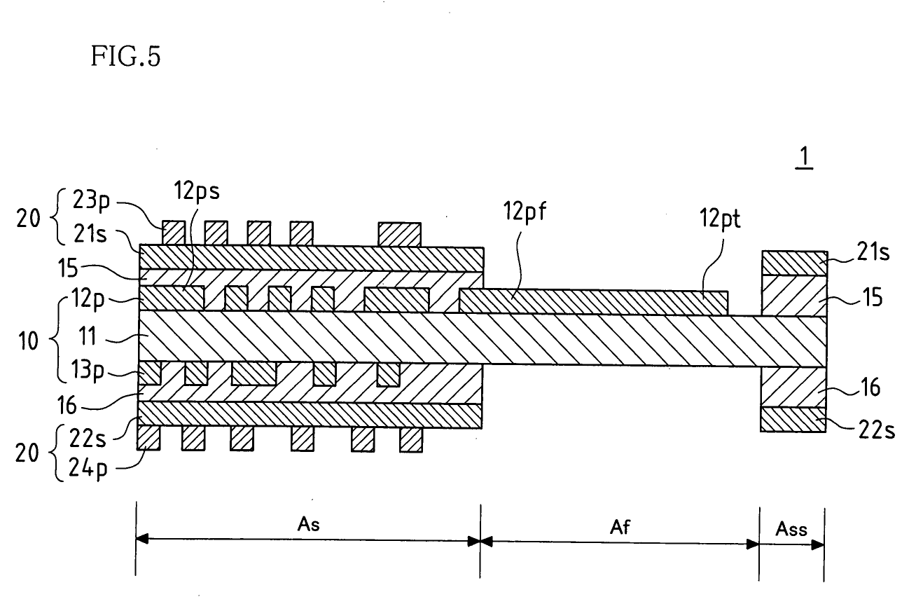

FIG. 5 is a cross-sectional diagram that shows a cross-section of a state in which a hard base material of a region that corresponds to a flexible portion has been removed, in a multilayer printed wiring board according to Embodiment 1 of the present invention.

After the outer layer circuit patterns 23p and 24p (FIG. 4) are formed, the hard base material 20 in a region that corresponds to the flexible portion Af is removed. Thus, a state is created in which insulation layers 21s and 22s of the hard base material 20 are disposed left remaining in a region that corresponds to the hard portions As and Ass.

The method for removing the hard base material 20 is not directly related to the present invention, and so the details of that method are omitted, but as described as Conventional Example 1, various methods are possible, such as a method in which a slit is inserted in the hard base material 20 of the border of the flexible portion Af and the hard portion As, and punching the periphery of the flexible portion Af with a metal die.

Basically, if the following two conditions are satisfied, the hard base material 20 of the region that corresponds to the flexible portion Af may be removed with any sort of method. That is, it is sufficient if conditions are met that (1) even after the hard base material 20 of the region that corresponds to the flexible portion Af is removed, a processing work size (size of the outer shape of the multilayer printed wiring board 1 during processing) and shape is maintained such that there are no hindrances to subsequent covering layer formation processing (see FIG. 6) or surface treatment (see FIG. 7), and (2) that when using a method such as electrical plating in surface treatment, a necessary plating lead is insured.

FIG. 6 is a cross-sectional diagram that shows a cross-section of a state in which a covering layer has been formed across the border of a flexible portion and a hard portion, in a multilayer printed wiring board according to Embodiment 1 of the present invention.

After the hard base material 20 of the position that corresponds to the flexible portion Af is removed (FIG. 5), a covering layer 30 that continuously covers the flexible base material 10 and the hard base material 20 is formed in a state in which the exposed portion 12pt, which becomes a terminal portion when complete and is a portion of the inner layer circuit pattern 12p, has been exposed. It is sufficient if, on the side that the inner layer circuit pattern 13p that corresponds to the flexible portion Af is not present, a covering layer 31 is formed only in the region that corresponds to the hard portion As, in the same manner as the covering layer 30.

Also, in the covering layers 30 and 31 that correspond to the hard portion As, by patterning so as to correspond to the outer layer circuit patterns 23pt and 24pt that become subjects of surface treatment in the same manner as the exposed portion 12pt, the outer layer circuit patterns 23pt and 24pt are exposed.

By adopting a polyimide film base insulating resin film specification, it is possible to form the covering layer 30 that corresponds to the hard portion As and the covering layer 30 that corresponds to the flexible portion Af by layering one covering layer 30. That is, the covering layers 30 and 31 operate as coverlays, and can be configured with insulating resin film of the same material (same raw material) and approximately the same thickness as the insulation layer 11 of the flexible base material Af. By using the same raw material in the covering layers 30 and 31 and the insulation layer 11, it is possible to configure the multilayer printed wiring board 1 with high manufacturability and reliability.

Also, the covering layers 30 and 31 can be configured with an insulating resin such as polyimide, polyether ketone, polyester, or a liquid crystal polymer. Because these resins are applicable, it is possible to configure the multilayer printed wiring board 1 for which materials are easy to acquire, and that has high reliability and is easy to manufacture.

With the conventional technology, there is a large difference in the thickness of the flexible portion Af and the hard portion As, so even if an attempt is made to adopt a configuration in which the covering layer is formed continuously from the flexible portion Af to the hard portion As, a space is easily left remaining in which filling is incomplete at the height difference at the border B of the flexible portion Af and the hard portion As, which is indicated by the arrow B, so such a configuration is difficult to realize.

However, according to the present embodiment, by controlling the thickness of the adhesive layers 15 and 16, and the insulation layers 21 and 22 of the hard base material 20, so that flow is appropriately controlled when layering, it is possible to reduce thickness within the range possible, so the height difference of the border B can be reduced, and thus complete filling of the height difference of the border B is possible.

FIG. 7 is a cross-sectional diagram that shows a cross-section of a state in which surface treatment has been performed after forming a covering layer, in a multilayer printed wiring board according to Embodiment 1 of the present invention.

Next after the processing in FIG. 6, if necessary a plating resist is additionally formed, gold, tin, or other metal plating, or rust-proofing processing, are performed together for the outer layer circuit patterns 23pt and 24pt of the hard portion As and the exposed portion 12pt of the flexible portion Af, forming plating layers 37, 38, and 39. In the present embodiment, the covering layers 30 and 31 that correspond to the hard portion As, and the covering layer 30 that corresponds to the flexible portion Af, are also used as a resist layer for surface treatment.

After the surface treatment, same as in the conventional processing method, symbol printing or subsequent post-processing treatment, outer shape processing in which severing is performed at a severing line DL, and the like are performed, configuring the multilayer printed wiring board 1 as a completed component.

The difference in thickness (height difference) of the hard portion As and the flexible portion Af is small, and moreover, the covering layer 30 is formed at the border B of the hard portion As and the flexible portion Af, and the thickness changes smoothly, so even in the surface treatment process, it is possible to form a plating resist, which ordinarily has low filability, without a problem, and it is also possible to reliably perform physical polishing or the like as pre-processing.

As described above, in the present embodiment, unlike in the conventional method, covering layer formation and surface treatment such as plating are not performed in the processing from after inner layer (the inner layer circuit patterns 12p and 13p) formation to outer layer (the outer layer circuit patterns 23p and 24p) formation, and thus it is possible to address the problems in the conventional technology.

That is, the effects as indicated in (1) to (4) below are obtained.

(1) Because a resin layer of polyimide or the like, which is comparatively difficult to bond, is not included as the hard base material 20 that constitutes the outer layer of the hard portion As, interlayer adhesive strength is easily obtained, and a through-hole can be formed with high reliability.

(2) In the processing from after inner layer formation to outer layer formation, the covering layer (coverlay) layering process, which is a heating/pressing process that cause changes in dimensions or distortions, is not included, so the inner layer circuit patterns 12p and 13p can be finished with good dimensional precision, and positioning of the inner layer circuit patterns 12p and 13p and the outer layer circuit patterns 23p and 24p can be performed precisely, so simplification of processing and shortening of processing time are possible, and moreover, it is possible to easily manufacture the multilayer printed wiring board 1 so that it has high precision and high density.

(3) The covering layer 30 is continuously formed in a state straddling the border B of the flexible portion Af and the hard portion As, where flexibility is a problem in a conventional structure, so that strength-wise discontinuity is improved, and thus stable, high flexibility properties can be realized.

(4) Because there is no change in the dimensions of the inner layer accompanying surface processing (wet processing or dry processing such as plating, and physical processing such as polishing or the like), the inner layer circuit patterns 12p and 13p can be finished with good dimensional precision, and positioning of the inner layer circuit patterns 12p and 13p and the outer layer circuit patterns 23p and 24p can be performed precisely, so simplification of processing and shortening of processing time are possible, and moreover, it is possible to easily manufacture the multilayer printed wiring board 1 so that it has high precision and high density.

Also, in the present embodiment, as stated below, it is significant that the covering layer 30 is in the outermost layer (that processing is performed last).

In the present embodiment, the covering layers 30 and 31 do not receive pressure or temperature except with the object of layering and bonding the covering layers 30 and 31 themselves. Moreover, the surface thereof is the side that faces layering cushion material for applying layering pressure, and is formed in a state in which basically no damage has been received in the surface. That is, damage or depressions, discontinuity, or the like in the surface of the outermost layer are the factors that most affect flexibility properties, without citing an example such as a spring, but on this point, the present embodiment is extremely advantageous.

Also, by applying appropriate pressure and temperature when layering, the bonded side of the covering layer 30 (the hard base material 20 side) is formed with appropriate deformation and flow, and a small height difference at the border B, so structural (thickness) and strength-wise discontinuities due to the hard base material 20 (the insulation layer 21s) from the hard portion As to the flexible portion Af, and the adhesive layer 15, can be alleviated, and it is possible to configure a function to avoid concentration of stress on the border B of the hard portion. As and the flexible portion Af, which is most easily broken.

In the present embodiment, in order to simplify the description, the multilayer printed wiring board 1 was described with five layers, in which the flexible portion Af is a one-layer conductor layer pattern (the first conductor layer pattern 12p), and the hard portion As has four layers (the first conductor layer pattern 12p, the second conductor layer pattern 13p, the third conductor layer pattern 23p, and the fourth conductor layer pattern 24p). However, the present embodiment can be applied to a multilayer printed wiring board with various numbers of layers, having a total of three, four, or six or more layers. Also, the present embodiment can be applied to a multilayer printed wiring board with any kind of structure or manufacturing process, such as a laser method/photo via method/buildup method, various hole-punching methods, pattern formation methods, and the like.

### Embodiment 2

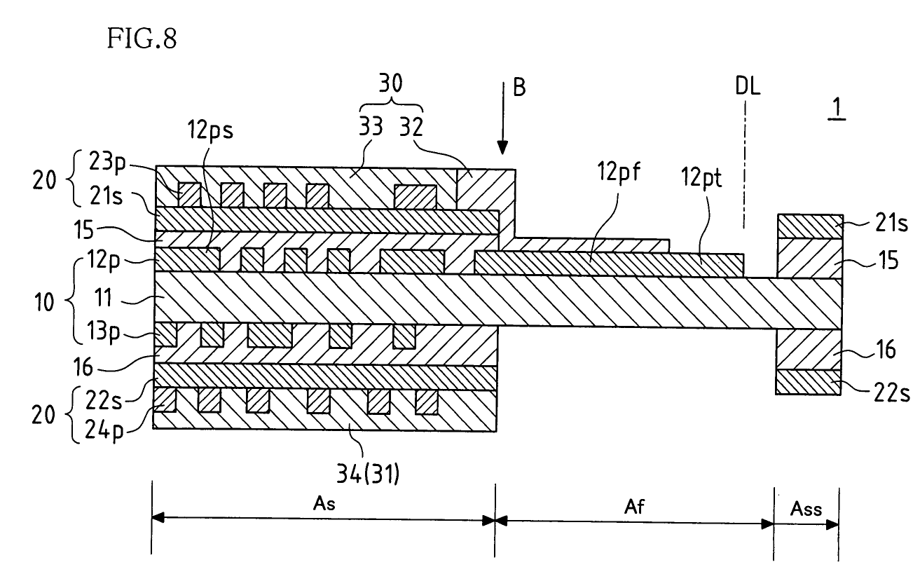

FIG. 8 is a cross-sectional diagram that shows a cross-section of a state in which a covering layer has been formed, in a multilayer printed wiring board according to Embodiment 2 of the present invention. The same configurations as in Embodiment 1 have the same reference numerals, and a detailed description thereof is omitted here.

The present embodiment is nearly the same as Embodiment 1, but here the configuration of the covering layers 30 and 31 in Embodiment 1 is modified.

In the present embodiment, instead of the covering layers 30 and 31 formed in Embodiment 1, covering layers 32, 33, and 34 are formed. That is, corresponding to the covering layer 30, a first covering layer 32 that continuously covers a partial region of the hard base material 20 and the flexible base material 10, and a second covering layer 33 that covers a region other than the partial region of the hard base material 20, are formed, and corresponding to the covering layer 31, a covering layer 34 that covers the hard base material 20 on the opposite side is formed. Same as in Embodiment 1, the first covering layer 32 covers the flexible base material 10 in a state in which the exposed portion 12pt has been exposed,

The first covering layer 32 is formed with insulating resin film, and the second covering layer 33 and the covering layer 34 are formed with a raw material that is the same as or different from the first covering layer 32. For example, in the second covering layer 33 and the covering layer 34, a plurality of types of materials can be used together depending on the region. For example, the second covering layer 33 and the covering layer 34 can be formed with insulating resin film or insulating resin ink (photosensitive ink resist).

### Embodiment 3

In the process of layering the hard base material 20 according to Embodiment 1, the hard base material 20 of the region that corresponds to the flexible portion Af and the flexible base material 10, although the adhesive layers 15 and 16 are not present, is fitted very well with pressure and heat when layering.

Accordingly, in order to peel away the hard base material 20 of the region that corresponds to the flexible portion Af without deforming or damaging the flexible portion Af, careful work is necessary, and defects easily occur. Also, because processing work is performed on a one-by-one basis for each multilayer printed wiring board 1, work efficiency also is very poor. As described below, in the present embodiment such problems do not occur.

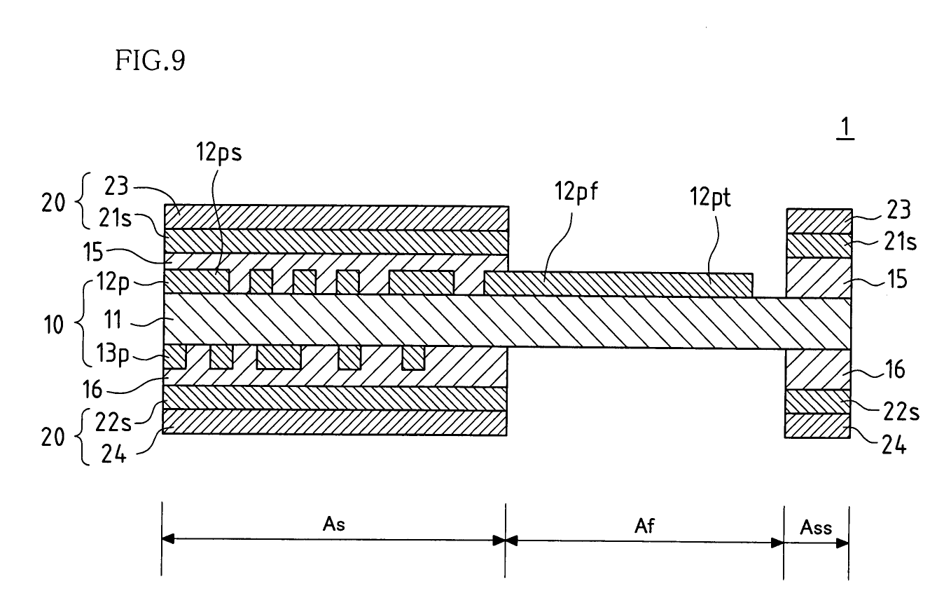

FIG. 9 is a cross-sectional diagram that shows a cross-section of a state in which a hard base material that constitutes an outer layer has been formed outside of an inner layer, in a multilayer printed wiring board according to Embodiment 3 of the present invention. The same configurations as in Embodiments 1 and 2 have the same reference numerals, and a detailed description thereof is omitted here.

The processing that forms the flexible base material 10 that constitutes an inner layer is the same as in Embodiment 1 . Next, the hard base material 20 is layered via the adhesive layers 15 and 16. The hard base material 20 of the region that corresponds to the flexible portion Af (and if necessary, the adhesive layers 15 and 16) are punched with a metal die or the like in advance. That is, the insulation layers 21s and 22s that correspond to the hard portions As and Ass are layered on the adhesive layers 15 and 16.

In the present embodiment, material with a thickness of 50 microns in which copper foil has been layered on a semi-hardened glass cloth-containing epoxy is used for the hard base material 20, but same as in Embodiments 1 and 2, it is also possible to adopt a configuration with a combination such as an adhesive layer and a one-sided flexible wiring board material.

With this configuration, work to remove the hard base material 20 that corresponds to the flexible portion Af is not necessary, so it is possible to dramatically save labor in processing and thus improve work efficiency. Also, layering and pressing of the covering layer, which is a heat layering process, is not performed in the processing after inner layer formation and before outer layer formation, so, it is possible to easily manufacture a multilayer printed wiring board with high dimensional precision and wiring density, and high precision of positioning of the inner layer circuit patterns 12p and 13p and the outer layer circuit patterns 23p and 24p (not shown) relative to each other.

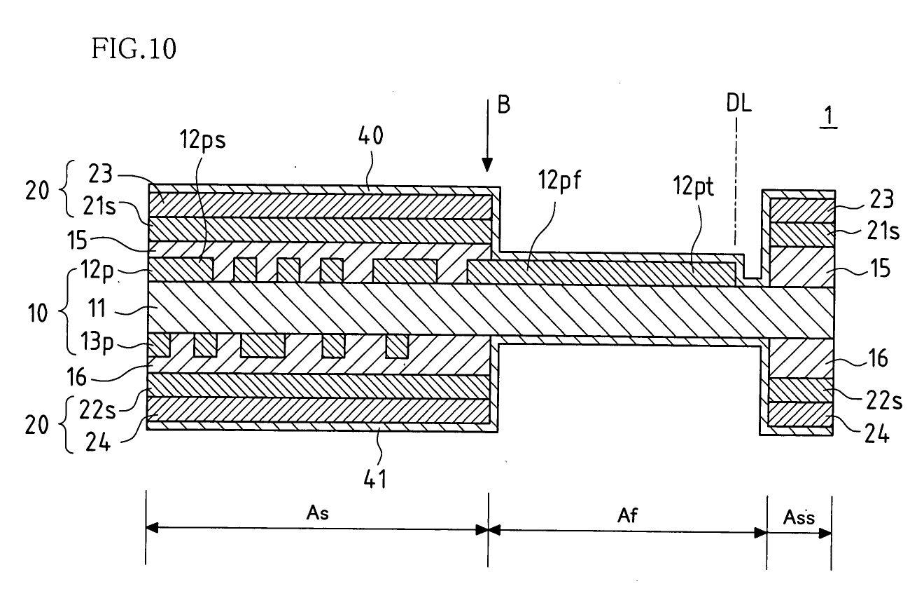

FIG. 10 is a cross-sectional diagram that shows a cross-section of a state in which a photosensitive resist for forming an outer layer circuit pattern in a hard base material has been formed, in a multilayer printed wiring board according to Embodiment 3 of the present invention.

After the hard base material 20 is layered (FIG. 9), the outer layer circuit patterns 23p and 24p (not shown) of the hard portion As are formed by applying ordinary photolithography technology. FIG. 9 shows a state in which photosensitive resists 40 and 41, known as dry film, have been formed as outer layer circuit pattern etching resists for forming the outer layer circuit patterns 23p and 24p.

The photosensitive resists 40 and 41 are formed as a single body corresponding to regions (the hard portions As and Ass) necessary for formation of the outer layer circuit patterns 23p and 24p, and the flexible portion Af (the inner layer circuit patterns 12pf and 12pt) of the flexible base material 10.

In the present embodiment, same as in Embodiments 1 and 2, there is little difference in the thickness of the hard portion As and the thickness of the flexible portion Af, so it is possible to reduce the height difference at the border B of the hard portion As and the flexible potion Af, and thus, same as the covering layer 30 of Embodiment 1 and the first covering layer 32 of Embodiment 2, it is possible to reliably fill the border B with dry film (the photosensitive resists 40 and 41). Accordingly, a method (the present embodiment) is possible in which after layering the hard base material 20, the photosensitive resists 40 and 41 used as outer layer circuit pattern etching resists are formed, and the outer layer circuit patterns 23p and 24p are formed.

Depending on the filability of the layer structure and the dry film, when filling at the border B is insufficient with only the dry film, it is possible to form an additional layer (not shown) in the flexible portion Af. The additional layer functions the same whether it is formed as a layer above or a layer below a photosensitive resist.

As the additional layer, it is possible to apply a method in which another sheet of dry film is formed, a method in which separate types of ink or film dissolved or separated by peeling in a dry film peeling separation process are formed with a printing method or other method, thus forming a two-layer structure, or alternatively, a method in which a photosensitive liquid resist and dry film are both used. Also, if a printing method is used, it is possible to easily configure a two-layer structure.

After forming the outer layer circuit patterns 23p and 24p (not shown, see FIG. 4) by applying photolithography technology in a state in which the inner layer circuit patterns 12pf and 12pt of the flexible portion Af which have already been formed are protected by applying the photosensitive resists 40 and 41, the photosensitive resists 40 and 41 are removed.

Subsequent processing is the same as in Embodiments 1 and 2. Covering layer formation, surface treatment such as plating layer formation, symbol printing and other post-processing treatment, outer shape processing that severs at the severing line DL, and the like are performed, resulting in the completed multilayer printed wiring board 1.

The present invention may be embodied in various other forms without departing from the gist or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

What is claimed is:

1. A multilayer printed wiring board comprising: a flexible portion that is constituted from a flexible base material in which an inner layer circuit pattern has been formed, and a hard portion that is constituted from a hard base material that is layered on a portion of the flexible base material and in which an outer layer circuit pattern has been formed, and a covering layer that continuously covers the flexible base material and the hard base material, with an exposed portion of the inner layer circuit pattern being exposed.

2. The multilayer printed wiring board according to claim 1, wherein the covering layer is insulating resin film.

3. The multilayer printed wiring board according to claim 1, wherein the covering layer is formed with the same raw material as an insulation layer of the flexible base material.

4. The multilayer printed wiring board according to claim 1, wherein the covering layer is formed with any one selected from the group consisting of polyimide, polyether ketone, polyester, and liquid crystal polymer.

5. The multilayer printed wiring board according to claim 1, wherein the covering layer comprises a first covering layer that continuously covers a partial region of the hard base material and the flexible base material, and a second covering layer that covers a region other than the partial region of the hard base material.

6. The multilayer printed wiring board according to claim 5, wherein the first covering layer is insulating resin film, and the second covering layer is formed with the same material or a different material than the first covering layer.

7. The multilayer printed wiring board according to claim 6, wherein the second covering layer is formed with insulating resin film or insulating resin ink.

8. A method for producing a multilayer printed wiring board comprising a flexible portion that is constituted from a flexible base material in which an inner layer circuit pattern has been formed, and a hard portion that is constituted from a hard base material that is layered on a portion of the flexible base material and in which an outer layer circuit pattern has been formed, the method comprising:
a step of patterning a conductor layer of the flexible base material to form the inner layer circuit pattern, and
a step of bonding the hard base material in a region that corresponds to the hard portion of the flexible base material in which the inner layer circuit pattern was formed, and
a step of forming a covering layer that continuously covers the flexible base material and the hard base material, with an exposed portion of the inner layer circuit pattern being exposed, and
a step of performing surface treatment for the exposed portion of the inner layer circuit pattern after the covering layer is formed.

9. The method for producing a multilayer printed wiring board according to claim 8, further comprising a step of patterning a conductor layer of the hard base material to form the outer layer circuit pattern before forming the covering layer, and wherein in the step of performing surface treatment, surface treatment for the outer layer circuit pattern is performed at the same time.

10. The method for producing a multilayer printed wiring board according to claim 9, wherein an outer layer circuit pattern etching resist used when forming the outer layer circuit pattern is formed as a single body in the hard portion and the flexible portion.

11. The method for producing a multilayer printed wiring board according to claim 10, wherein an additional layer is formed in the outer layer circuit pattern etching resist formed in the flexible portion.

12. The method for producing a multilayer printed wiring board according to claim 11, wherein either one of the outer layer circuit pattern etching resist and the additional layer is formed with a printing method.

13. A method for producing a multilayer printed wiring board comprising a flexible portion that is constituted from a flexible base material in which an inner layer circuit pattern has been formed, and a hard portion that is constituted from a hard base material that is layered on a portion of the flexible base material and in which an outer layer circuit pattern has been formed, the method comprising:
a step of patterning a conductor layer of the flexible base material to form the inner layer circuit pattern, and
a step of bonding the hard base material in a region that corresponds to the hard portion of the flexible base material, such that the hard base material is faced toward the flexible base material in which the inner layer circuit pattern was formed, and
a step of patterning a conductor layer of the hard base material to form the outer layer circuit pattern, and
a step of removing the hard base material of a region that corresponds to the flexible portion, and
a step of forming a covering layer that continuously covers the flexible base material and the hard base material, with an exposed portion of the inner layer circuit pattern being exposed.

14. The method for producing a multilayer printed wiring board according to claim 13, wherein bonding of the hard base material is performed on both sides of the flexible base material, with the hard base material arranged on both sides of the flexible base material.

15. The method for producing a multilayer printed wiring board according to claim 13, further comprising a step of performing surface treatment for at least one of the exposed portion and the outer layer circuit pattern, after the covering layer is formed.

16. The method for producing a multilayer printed wiring board according to claim 13, wherein the covering layer comprises a first covering layer that continuously covers a partial region of the hard base material and the flexible base material, and a second covering layer that covers a region other than the partial region of the hard base material.

17. The method for producing a multilayer printed wiring board according to claim 16, wherein the first covering layer and the second covering layer are insulating resin films that have been formed as a single body.

18. The method for producing a multilayer printed wiring board according to claim 16, wherein the first covering layer and the second covering layer are photosensitive resists that have been formed as a single body.

19. The method for producing a multilayer printed wiring board according to claim 16, wherein either the first covering layer is insulating resin film and the second covering layer is a photosensitive resist, or the first covering layer is a photosensitive resist and the second covering layer is insulating resin film.
